(19) United States
(12) Patent Application Publication
(10) Pub. No.: US 2024/0347317 A1
(43) Pub. Date: Oct. 17, 2024

(54) Method and System for Plasma Processing

(71) Applicant: Tokyo Electron Limited, Tokyo (JP)

(72) Inventors: Qiang Wang, Austin, TX (US); Michael Hummel, Austin, TX (US); Peter Lowell George Ventzek, Austin, TX (US); Alok Ranjan, Austin, TX (US); Mitsunori Ohata, Taiwa-cho (JP)

(21) Appl. No.: 18/298,829

(22) Filed: Apr. 11, 2023

(51) Int. Cl. H01J 37/32

(52) U.S. Cl. CPC H01J 37/3211; H01J 37/32146; H01J 37/32183; H01J 2237/24564

(57) ABSTRACT

A resonator antenna system for a plasma processing tool includes a resonator antenna coupled to a RF source at a first point on the resonator antenna, a current balancing circuit coupled to the resonator antenna at a second point on the resonator antenna, a first current sensor coupled between the RF source and the resonator antenna, and a second current sensor coupled between the current balancing circuit and the resonator antenna. The current balancing circuit includes a variable component. The current balancing circuit is further coupled to a ground terminal.

### TECHNICAL FIELD

The present disclosure generally relates to semiconductor processing technology and, in particular embodiments, to a method and system for plasma processing.

### BACKGROUND

Plasma processing is extensively used in the manufacturing and fabrication of high-density microscopic circuits within the semiconductor industry. In a plasma processing system, an electromagnetic wave radiated into a plasma chamber generates an electromagnetic field within the chamber. The generated electromagnetic field heats electrons in the chamber. The heated electrons ignite a plasma that treats the substrate in a process such as for etching, deposit, oxidation, sputtering, or the like.

A non-uniform electromagnetic field within the plasma processing chamber results in a non-uniform treatment of the substrate due to different portions of the substrate being treated with varying densities of plasma. An apparatus and system that allows for the control of plasma uniformity and thus better results in etching and deposition processes is desirable.

### SUMMARY

In accordance with an embodiment, a resonator antenna system for a plasma processing tool includes: a resonator antenna coupled to a RF source at a first point on the resonator antenna; a current balancing circuit coupled to the resonator antenna at a second point on the resonator antenna, the current balancing circuit including a first variable component, the current balancing circuit being further coupled to a ground terminal; a first current sensor coupled between the RF source and the resonator antenna; and a second current sensor coupled between the current balancing circuit and the resonator antenna.

In accordance with another embodiment, a method for plasma processing includes: powering a resonator antenna with an RF source, the resonator antenna being above a plasma chamber, the RF source being coupled to the resonator antenna through a first current sensor, the resonator antenna being coupled to a ground terminal through a second current sensor; measuring a first current with the first current sensor and a second current with the second current sensor; based on a difference between the first current and the second current, adjusting a variable component of a current balancing circuit, the current balancing circuit being coupled between the second current sensor and the ground terminal; and performing a plasma process in the plasma chamber with a plasma generated by the resonator.

In accordance with yet another embodiment, a plasma processing system includes: a plasma processing chamber; a resonator antenna outside the plasma processing chamber, the resonator antenna coupled to an RF source at a first point on the resonator antenna, a matching circuit and a first current sensor being coupled between the RF source and the first point; and a ground terminal coupled to a second point on the resonator antenna, a length of the resonator antenna from the second point to an end of the resonator antenna being equal to a quarter-wavelength of a frequency of operation of the resonator antenna, a second current sensor and a filter circuit being coupled between the second point and the ground terminal.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a diagram of a plasma processing system, in accordance with some embodiments;

FIG. 2 illustrates a diagram of a matching circuit, in accordance with some embodiments;

FIG. 3 illustrates a diagram of a resonator antenna, in accordance with some embodiments;

FIG. 4 illustrates a schematic of a current balancing circuit, in accordance with some embodiments;

FIGS. 5A-5F illustrate schematics of current balancing circuits, in accordance with some other embodiments;

FIG. 6 illustrates a graph of experimental results for a current balancing circuit, in accordance with some embodiments;

FIG. 7 is a process flow chart diagram of a method for achieving current balancing, in accordance with some embodiments; and

FIG. 8 is a process flow chart diagram of a method for plasma processing, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

While inventive aspects are described primarily in the context of resonating structures in a plasma processing system, the inventive aspects may be similarly applicable to fields outside the semiconductor industry. Plasma can be used to treat and modify surface properties through functional group addition. For example, to treat surfaces for paint deposit, plasma can convert hydrophobic surfaces to hydrophilic surfaces. Further, the inventive aspects are not limited to plasma. For example, RF can be used to thaw out frozen food or dry out textiles, food, wood, or the like. In these various examples and across industries, a uniformly generated plasma as disclosed herein is advantageous.

In various embodiments, the arrangement of the various components are illustrated symmetrically to provide, for example, uniformity within the system. However, it should be appreciated that such symmetry is not required, and non-symmetrical arrangements may be purposefully introduced to correct, for example, non-uniformity within the system or to generate a skewed chamber effect.

According to one or more embodiments of the present disclosure, this application relates to current balancing circuits and methods of balancing coil currents for plasma uniformity control. Generally, a radiating antenna (e.g., a dipole resonator or resonator coil) is used to radiate an RF wave that generates an electromagnetic field within a plasma chamber. The electromagnetic field ignites and sustains plasma within the plasma chamber. Uniformity of the plasma distribution may be dependent on the uniformity of the electromagnetic field. Achieving plasma uniformity may benefit from additional tuning mechanisms for delivering uniform electromagnetic field to the plasma chamber and thereby generate uniform plasma within the chamber, e.g. for deposition or etching processes performed on a wafer in the plasma chamber. In particular, different coil sections of a resonator antenna may carry different amounts of current due to, e.g., operational conditions, uneven loads on the different coil sections, asymmetries of the plasma chamber, or other components such as absorption coils affecting the current densities. In order to compensate for unbalanced current amounts in different coil sections, a current balancing circuit may be coupled between the resonator antenna and a ground feed of the resonator source. The current balancing circuit provides a mechanism for adjusting the current balance between different sections of the resonator coil (e.g., inner and outer coil sections) and thereby deliver balanced electromagnetic field to the plasma chamber. Plasma uniformity in the plasma chamber can be tuned by adjusting the current ratio between the resonator coil sections. This can be achieved by adjusting variable settings (e.g., capacitance, inductance, resistance, or the like) in the current balancing circuit. The present disclosure includes embodiments of current balancing circuits and control algorithms for operating a system with a current balancing circuit to balance currents in different coil segments.

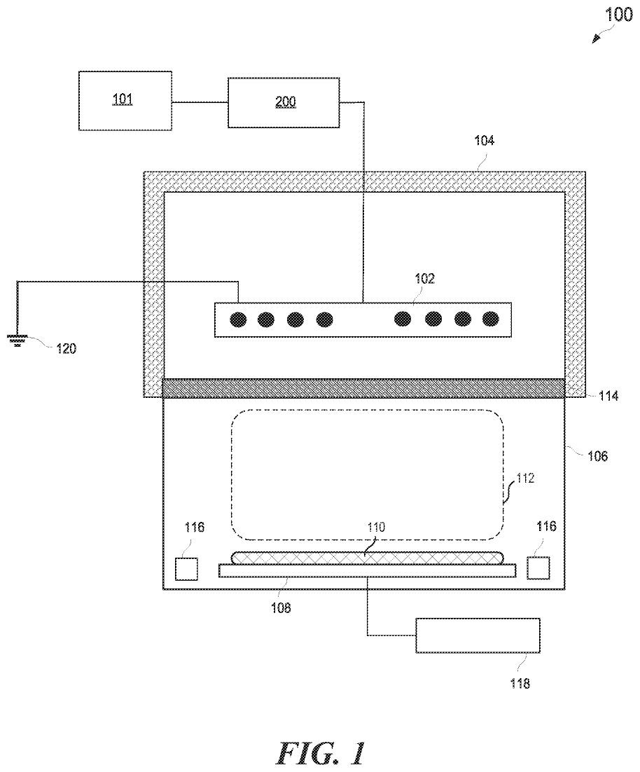

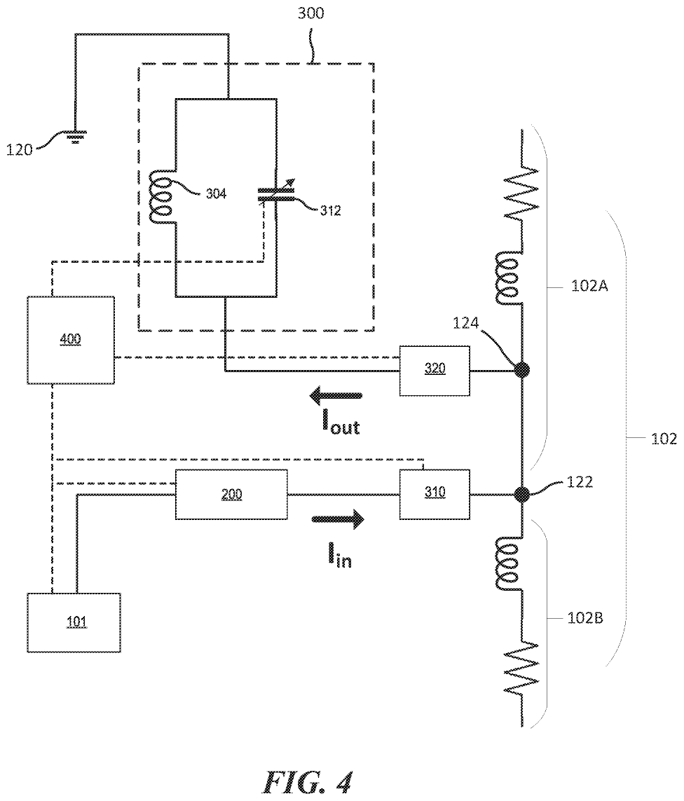

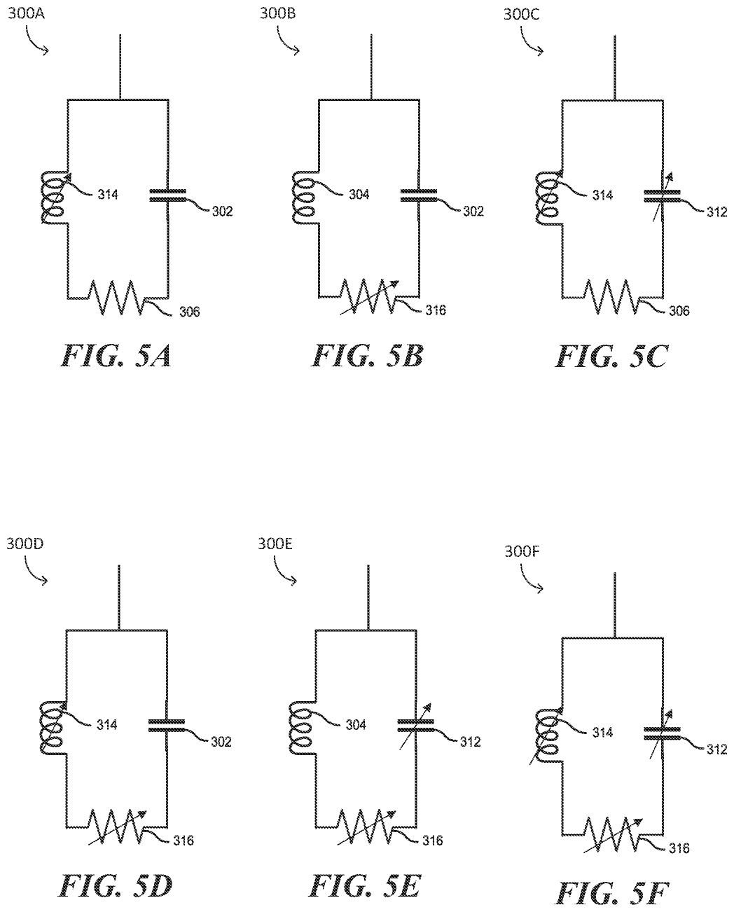

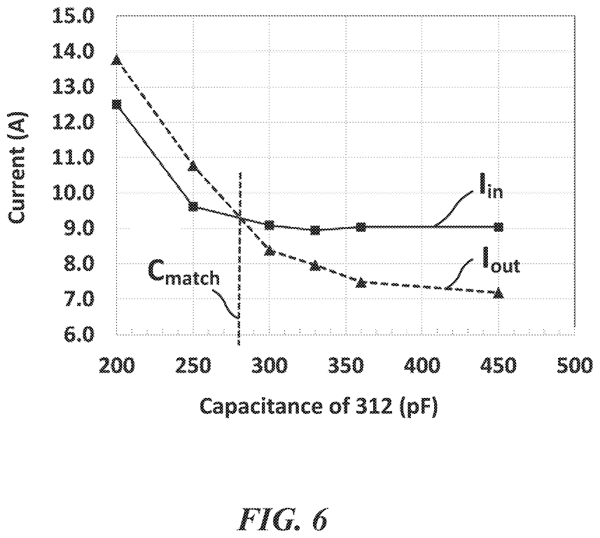

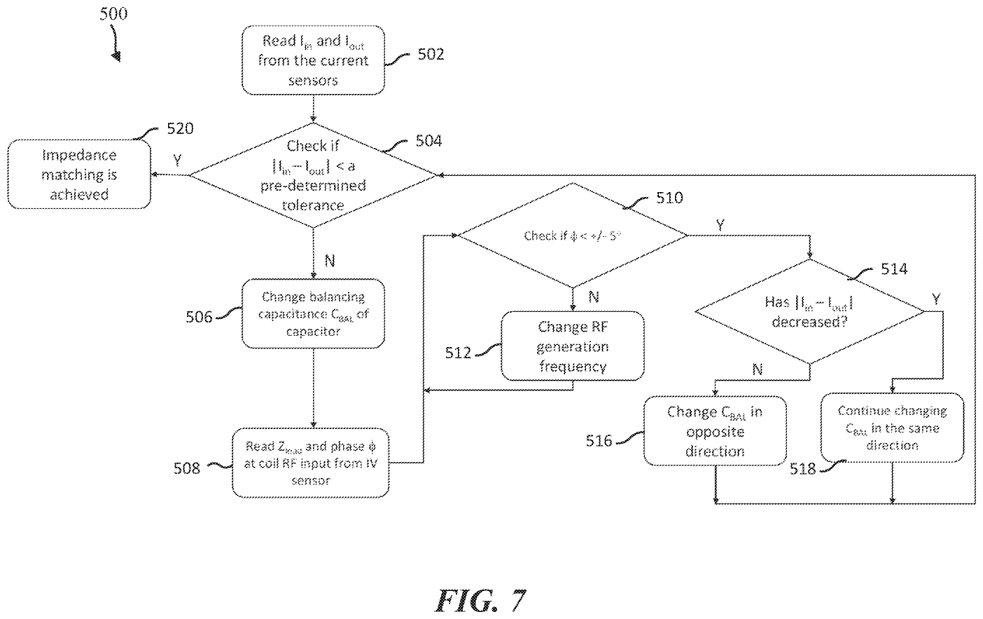

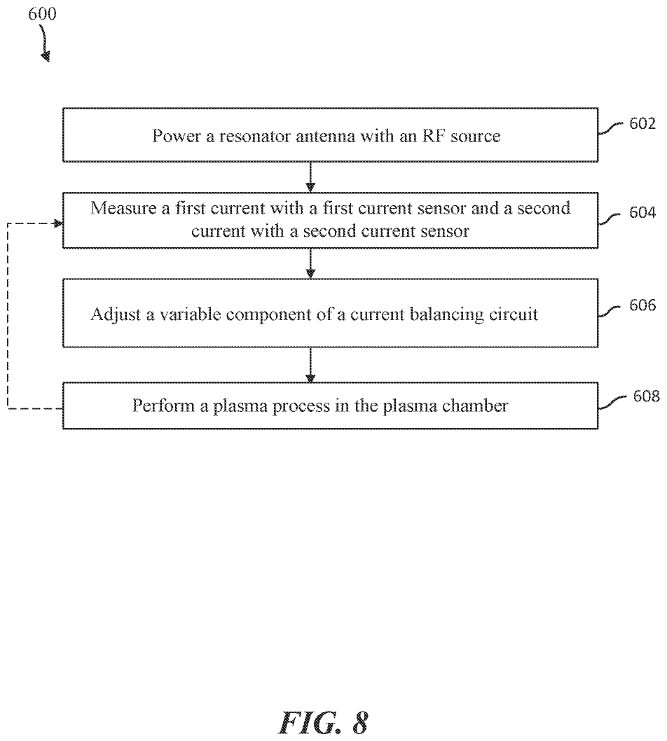

Embodiments of the disclosure are described in the context of the accompanying drawings. An embodiment of a plasma processing system with a matching circuit and a resonator antenna will be described using FIGS. 1-3. An embodiment of a current balancing circuit will be described using FIG. 4. Embodiments of other current balancing circuits will be described using FIGS. 5A-5F. Experimental results for a current balancing circuit will be described using FIG. 6. An embodiment of a method for achieving current balancing will be described using FIG. 7. An embodiment of a method for plasma processing will be described using FIG. 8.

FIG. 1 illustrates a diagram of an embodiment plasma processing system 100, in accordance with some embodiments. Plasma processing system 100 includes a matching circuit 200, a resonator antenna 102 (also referred to as a resonator coil or dipole resonator), a housing structure 104, a plasma processing chamber 106, and, optionally, a dielectric plate 114, which may (or may not) be arranged as illustrated in FIG. 1. Further, plasma processing system 100 may include additional components not depicted in FIG. 1.

In various embodiments, resonator antenna 102 is coupled to an RF source 101 through a matching circuit 200. RF source 101 includes an RF power supply, which may include a generator circuit. RF source 101 provides forward RF waves to resonator antenna 102, which are radiated towards plasma processing chamber 106. Throughout the description, the RF source 101 may be alternatively referred to as a power supply or RF source.

RF source 101 is coupled to matching circuit 200 and matching circuit 200 is coupled to resonator antenna 102 via power transmission lines, such as coaxial cables or the like. The RF source 101 may be employed to provide RF power to the resonator antenna 102 as a continuous wave (CW). In an embodiment, the RF source 101 may be employed to provide pulse-modulated RF power to the resonator antenna 102. The RF source 101 may provide pulse-modulated RF power to the resonator antenna 102 at a modulation frequency that is in a range from 10 Hz to 1000 kHz. In addition, the RF source 101 may provide pulse-modulated RF power to the RF source 101 at a duty cycle that is in a range from 10 percent to 90 percent.

In some embodiments, RF source 101 includes an IV sensor (also referred to as a current-voltage (IV) probe). The IV sensor may provide feedback on power and impedance matching to a controller (see below, FIG. 4), such as total impedance Z_{load} of the load coupled to the RF source 101 and phase ϕ of the RF power. The IV sensor may include a current sensor and a voltage sensor In some embodiments, the IV sensor has broadband capability, such as over a frequency range of 0.307 MHz to 252 MHz. However, any suitable IV sensor may be used, such as a IV sensor without broadband capability.

Plasma processing chamber 106 may be, e.g., a medium frequency (MF) or high frequency (HF) plasma chamber. The plasma processing chamber 106 may be a vacuum chamber. In some embodiments, the plasma processing chamber 106 is configured to operate plasma 115 at a first resonant frequency, wherein the first resonant frequency is in a range from about 1 MHz to about 27 MHz. For example, the plasma processing chamber 106 may be configured to operate plasma 115 at 1 MHz or more, 13.56 MHz or more, 27 MHz or more, or the like.

In various embodiments, plasma processing chamber 106 includes a substrate holder 108 (e.g., a chuck). As illustrated, substrate 110 is placed on substrate holder 108 to be processed. Optionally, plasma processing chamber 106 may include a bias power supply 118 coupled to substrate holder 108. The plasma processing chamber 106 may also include one or more pump outlets 116 to remove by-products from plasma processing chamber 106 through selective control of gas flow rates within. In various embodiments, pump outlets 116 are placed near (e.g., below/around the perimeter of) substrate holder 108 and substrate 110. In various embodiments, plasma processing chamber 106 may include additional substrate holders (not illustrated). In various embodiments, the placement of the substrate holder 108 may differ from that illustrated in FIG. 1. Thus, the quantity and position of the substrate holder 108 are non-limiting.

In various embodiments, resonator antenna 102 radiates an electromagnetic field toward the plasma processing chamber 106. The radiated electromagnetic field generates an azimuthally symmetric, high-density plasma within a plasma generating region 112 with low capacitively coupled electric fields. In various embodiments, resonator antenna 102 is an inductively coupled antenna, such as a planar coil wound in a flat helix (i.e., a stovetop antenna). In an embodiment, resonator antenna 102 includes arms connected to capacitive structures that generate the azimuthal symmetry. In various embodiments, the excitation frequency of the resonator antenna 102 is in the radio frequency range (10-400 MHz), which is not limiting, and other frequency ranges can similarly be contemplated. For example, inventive aspects disclosed herein equally apply to applications in the microwave frequency range.

In various embodiments, resonator antenna 102 includes resonant elements. The resonant elements can be arms that are electrically connected to capacitive structures. The arms and the capacitive structures are resonant with electromagnetic waves fed from the RF source 101.

In various embodiments, resonant elements sustain standing electromagnetic waves. The resonant elements are placed close to and parallel to the dielectric plate 114 such that the oscillating magnetic field from the resonant elements penetrates the plasma processing chamber 106. The time-varying magnetic field induces a time-varying electric field, which transfers energy to plasma electrons.

In various embodiments, the RF source 101 couples energy to an interface of the resonator antenna 102 to generate the standing electromagnetic waves from the resonator antenna 102. The RF source 101 is coupled to the interface via a transmission line in embodiments. It is desirable that the interface maintain the same or higher symmetry as the elements of resonator antenna 102 under rotation about the axis of symmetry.

Additionally illustrated is housing structure 104, which surrounds resonator antenna 102. Housing structure 104 is a conductive structure, which is electrically coupled to the RF ground of RF source 101 and, thus, RF grounded. In various embodiments, housing structure 104 includes openings to couple an RF feed path from RF source 101 to resonator antenna 102 and to couple resonator antenna 102 to a ground terminal.

In various embodiments, housing structure 104 is positioned adjacent to the top of the plasma processing chamber 106, such that dielectric plate 114 is sandwiched between housing structure 104 and plasma processing chamber 106. The resonator antenna 102, thus, generates electromagnetic waves that radiate through the dielectric plate 114 toward the plasma processing chamber 106.

In various embodiments, resonator antenna 102 is outside of plasma processing chamber 106 and is separated from plasma processing chamber 106 by the dielectric plate 114, which is typically made of a dielectric material. Dielectric plate 114 separates the low-pressure environment within plasma processing chamber 106 from the external atmosphere. It should be appreciated that resonator antenna 102 can be placed directly adjacent to dielectric plate 114. In various embodiments, resonator antenna 102 is separated from plasma processing chamber 106 by air. In various embodiments, the properties of the dielectric plate 114 are selected to minimize reflections of the RF wave from the plasma processing chamber 106. In other embodiments, resonator antenna 102 is embedded within the dielectric plate 114. In various embodiments, dielectric plate 114 is in the shape of a disk.

The dielectric plate 114 includes a first outer surface and a second outer surface. The first outer surface faces the plasma processing chamber 106. The second outer surface faces the resonator antenna 102. The second outer surface is above the first outer surface in a vertical direction.

In an embodiment, the resonator antenna 102 couples RF power from RF source 101 to the plasma processing chamber 106 to treat substrate 110. In particular, resonator antenna 102 radiates an electromagnetic wave in response to being fed the forward RF waves from RF source 101. The radiated electromagnetic wave penetrates from the atmospheric side (i.e., resonator antenna 102 side) of the dielectric plate 114 into plasma processing chamber 106. The radiated electromagnetic wave generates an electromagnetic field within the plasma processing chamber 106. The generated electromagnetic field ignites and sustains plasma in a plasma generating region 112 by transferring energy to free electrons within the plasma processing chamber 106. The generated plasma can be used for a plasma process to, for example, selectively etch or deposit material on substrate 110. The plasma process may include an etch process such as a Reactive Ion Etch (RIE) process, an Atomic Layer Etch (ALE) process or the like, a deposition process such as a Plasma-Enhanced Physical Vapor Deposition (PVD) process, a Plasma-Enhanced Chemical Vapor Deposition (CVD) process, an Atomic Layer Deposition (ALD) process or the like.

In various embodiments, the plasma generating region 112 is immediately below the nearest portion of the dielectric plate 114 to the plasma processing chamber 106. In various embodiments, the upper most surface of the plasma generating region 112 corresponds to the plane where the outer surface of the dielectric plate 114 faces the plasma processing chamber 106.

In FIG. 1, resonator antenna 102 is external to plasma processing chamber 106. In various embodiments, however, resonator antenna 102 can be placed internal to the plasma processing chamber 106. In such an embodiment, the plasma generating region 112 is immediately below the nearest portion of the resonator antenna 102 to the plasma processing chamber 106.

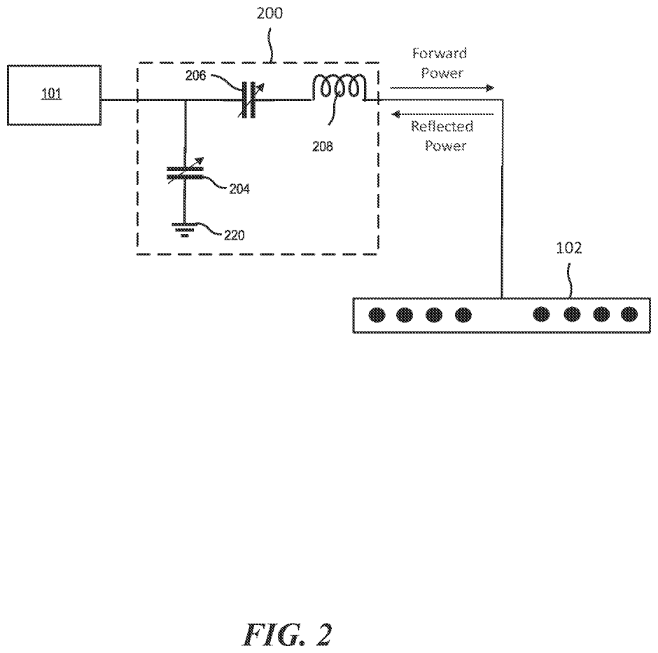

FIG. 2 illustrates a diagram of an example matching circuit 200, in accordance with some embodiments. An impedance associated with the plasma generated in the plasma processing chamber 106 corresponds to the load of the radiating resonator antenna 102 during its operation. The impedance of the plasma can vary based on, for example, changes in pressure, temperature, or operating conditions. Typically, a matching circuit (auto or manual) coupled to the radiating antenna is used to minimize losses (i.e., reflected power) in response to changes in the load condition. The matching circuit 200 (also referred to as a matching network or an impedance matching network) is coupled between the RF source 101 and the resonator antenna 102. As forward power propagates from the RF source 101 to the resonator antenna 102, some reflected power may be reflected back due to impedance mismatch between the plasma processing chamber 106 and the RF source 101. The matching circuit 200 is used to reduce reflected power by transforming the impedance looking into the matching circuit 200 (in other words, the impedance of the transmission lines, plasma process chamber 106, and resonator antenna 102) to a same impedance as the RF source 101 and any intermediate transmission lines. This increases the efficiency of supplying power to the plasma processing chamber 106.

The example matching circuit 212 includes a variable capacitor 204 coupled between the RF source 101 and ground, a variable capacitor 206 coupled between a node between the RF source 101 and the variable capacitor 204, and optionally an inductor 208 coupled between the variable capacitor 206 and the resonator antenna 102. The inductor 208 may be included selectively to achieve matching impedances for certain frequency ranges in order to achieve broadband RF capabilities. The variable capacitor 204 and the variable capacitor 206 may include moving parts such as motors that control relative positions of, e.g., parallel plates of the variable capacitor 204 and the variable capacitor 206 in order to control their respective capacitances.

It should be appreciated that the matching circuit 200 is illustrated in FIG. 2 as a non-limiting example of an impedance matching network. Any suitable matching circuit 200 including any suitable combination of impedance-adjustable variable components (e.g., variable or fixed capacitors, variable or fixed inductors, variable or fixed resistors, the like, or combinations thereof) is within the scope of the disclosed embodiments.

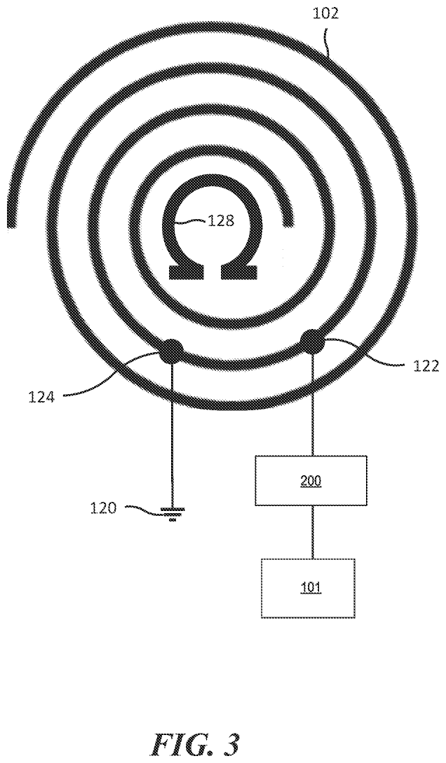

FIG. 3 illustrates the resonator antenna 102, in accordance with some embodiments. In some embodiments, the resonator antenna 102 is a planar coil which is designed to be a half-wave dipole antenna, with the total length of the resonator antenna 102 being equal to a half-wavelength at the frequency of operation (e.g., the first resonant frequency). As an example, the resonator antenna 102 may be a flat coil antenna or stovetop antenna made of a conductive material, e.g. a coil of copper tubing. However, any suitable materials and shape may be used for the resonator antenna 102. Because of the inclusion of the resonator antenna 102, the plasma processing system 100 may also be referred to as a resonator antenna system.

The RF source 101 may be coupled to the resonator antenna 102 (e.g., through the matching circuit 200) at a first point 122 on the resonator antenna 102. In addition, the resonator antenna 102 may be connected to a ground 120 (also referred to as a ground terminal 120, as it is a terminal of the circuit that is coupled to electrical ground) at a second point 124 on the resonator antenna 102. The length of the resonator antenna 102 from the second point 124 to either end of the resonator antenna 102 may be equal to a quarter-wavelength at the frequency of operation (e.g., the first resonant frequency).

Because the resonator antenna 102 operates by resonating with a plasma ignited and generated in the plasma processing chamber 106, the only connection to ground 120 may be through the second point 124 and each end of the resonator antenna 102 (in other words, the inner end and the outer end) may be left electrically floating. This configuration distinguished the resonator antenna 102 from various RF plasma excitation coils that are coupled to ground on both ends of the coil, such as through respective capacitors that may have varying capacitance.

Additionally, an absorption coil 128 may be present near the resonator antenna 102. The absorption coil 128 is part of an inductive loop that can adjust the resonant frequency of the resonator antenna 102, e.g. by changing the effective inductance of the resonator antenna 102 through mutual induction. In the illustrated example of FIG. 3, the absorption coil 128 is a loop of conductive material in the same plane as and surrounded by the coil of the resonator antenna 102. However, the absorption coil 128 may have any suitable shape and location relative to the resonator antenna 102. The absorption coil 128 may be coupled to ground on both ends, and on one or both ends the absorption coil 128 may be coupled to ground across a respective capacitor. A switch (e.g., a suitable MOSFET device) may be coupled between an end of the absorption coil 128 and ground. By opening and closing the switch, the inductive loop may be put into an open or closed state, thereby adjusting the amount of absorbed magnetic field and desirably changing the resonant frequency of the resonator antenna 102, such as to affect or control a plasma process.

Due to the absorption coil 128 taking power unevenly from different coil segments or other factors such as operational conditions, uneven loads on the different coil sections, or asymmetries in the resonator antenna 102 or the plasma processing chamber 106, the amounts of current flowing through different segments of the resonator antenna 102 while the RF source 101 is providing power may be different. This may lead to undesirable nonuniformities in the plasma generated in the plasma processing chamber 106. The unbalanced current may be addressed by a current balancing circuit coupled between the resonator antenna 102 and the ground 120.

FIG. 4 illustrates a schematic of an example current balancing circuit 300 coupled between the resonator antenna 102 and a ground 120, in accordance with some embodiments. The current balancing circuit provides a mechanism for adjusting the current balance between different sections of the resonator antenna 102 (e.g., an inner coil section 102A and an outer coil section 102B) and thereby deliver balanced electromagnetic field to the plasma chamber. As illustrated in FIG. 4, the resonator antenna 102 may be divided into an inner coil section 102A and an outer coil section 102B on either side of the first point 122. Both the inner coil section 102A and the outer coil section 102B receive RF power from the RF source 101 at the first point 122. Each of the inner coil section 102A and the outer coil section 102B are illustrated as having a respective inductor and a respective resistor in series that represent the respective inductance and resistance of the inner coil section 102A and the outer coil section 102B.

Due to various factors (e.g., the absorption coil 128, plasma processing chamber 106 asymmetries, or asymmetries in the structure of the resonator antenna 102), the current flowing in the inner coil section 102A and the outer coil section 102B may be different. This is equivalent to the current Iᵢₙ flowing into the resonator antenna 102 at the first point 122 being different from the current Iₒᵤₜ flowing out of the resonator antenna 102 at the second point 124, as through Ohm's law the electric current that flows into any junction in an electric circuit is equal to the electric current that flows out of the junction. The currents Iᵢₙ and Iₒᵤₜ may be balanced by coupling a current balancing circuit 300 between the second point 124 and the ground 120. The current balancing circuit 300 comprises one or more variable components that may be adjusted to change the impedance between the second point 124 and the ground 120 and thereby bring the absolute value of the difference between Iᵢₙ and Iₒᵤₜ (|Iᵢₙ−Iₒᵤₜ|) to be within a tolerance of 0 A to 0.2 A. This will balance the currents flowing in the inner coil section 102A and the outer coil section 102B, which may be advantageous for achieving plasma uniformity.

The example current balancing circuit 300 illustrated in FIG. 4 comprises a loop with an inductor 304 and a variable capacitor 312. As the capacitance of the variable capacitor 312 (also referred to as the balancing capacitance C_{BAL}) is changed, the impedance between the second point 124 and the ground 120 is changed, which can bring Iₒᵤₜ closer and Iᵢₙ. For example, the variable capacitor 312 may comprise a plurality of switch-capacitor networks connected in parallel. Each switch-capacitor network comprises a capacitor and a switch connected in series. By controlling the on and off of the switches of the plurality of switch-capacitor networks, the capacitance of the variable capacitor 312 varies accordingly. Alternatively, the variable capacitor 312 may have its capacitance changed by mechanical motion. For example, the distance and/or the overlapping area of the two plates of the variable capacitor 312 may be adjustable through a suitable mechanical construction. In some embodiments, the variable capacitor 312 is able to vary in a range from 200 pF to 500 pF. In other embodiments, any other acceptable methods for changing the capacitance of the variable capacitor 312 can be utilized.

In some embodiments, the current balancing circuit 300 is implemented in a same apparatus as the matching circuit 200. However, the current balancing circuit 300 is electrically separate from the matching circuit 200, as the current balancing circuit 300 is coupled between the ground 120 and the resonator antenna 102 and the matching circuit is coupled between the RF source 101 and the resonator antenna 102. In other embodiments, the current balancing circuit 300 is implemented in any other suitable location.

The example current balancing circuit 300 is just one possible current balancing circuit 300 that may be used. Any suitable filter circuit or resonant filter circuit (e.g., LC or RLC circuits) with one or more variable components can be used as a current balancing circuit 300. FIGS. 5A-5F below illustrate other example current balancing circuits that may be used to balance Iᵢₙ and Iₒᵤₜ.

In order to measure the currents Iᵢₙ and Iₒᵤₜ, a first current sensor 310 is coupled between the first point 122 and the RF source 101 (e.g., between the first point 122 and the matching circuit 200), and a second current sensor 320 is coupled between the second point 124 and the current balancing circuit 300. The first current sensor 310 measures Iᵢₙ and the second current sensor 320 measures Iₒᵤₜ.

A controller 400 may be used to automate the operation of the current balancing circuit 300. The controller 400 is configured to receive input from the first current sensor 310 (e.g., the value of Iᵢₙ) and the second current sensor 320 (e.g., the value of Iₒᵤₜ) and adjust the impedance of the current balancing circuit 300 (e.g., by changing the capacitance of the variable capacitor 312) and to balance Iᵢₙ and Iₒᵤₜ. In some embodiments, the controller 400 is further configured to automate the operation of the plasma processing system 100. As such, the controller 400 may be further configured to receive measurements from an IV sensor of the RF source 101 and adjust the output of the RF source 101 and to adjust the various variable components of the matching circuit 200. In some embodiments, the controller 400 includes a programmable processor, microprocessor, computer, or the like. Although the controller 400 is illustrated as a single element for illustrative purposes, the controller 400 may include multiple elements. The controller 400 may be programmable by instructions stored in software, firmware, hardware, or a combination thereof.

FIGS. 5A-5F illustrate various examples of current balancing circuits. FIG. 5A illustrates a current balancing circuit 300A comprising a capacitor 302, a variable inductor 314, and a resistor 306. FIG. 5B illustrates a current balancing circuit 300B comprising a capacitor 302, an inductor 304, and a variable resistor 316. FIG. 5C illustrates a current balancing circuit 300C comprising a variable capacitor 312, a variable inductor 314, and a resistor 306. FIG. 5D illustrates a current balancing circuit 300D comprising a capacitor 302, a variable inductor 314, and a variable resistor 316. FIG. 5E illustrates a current balancing circuit 300E comprising a variable capacitor 312, an inductor 304, and a variable resistor 316. FIG. 5F illustrates a current balancing circuit 300D comprising a variable capacitor 312, a variable inductor 314, and a variable resistor 316. Any of the current balancing circuits of FIGS. 5A-5F, or a combination thereof, may be used as the current balancing circuit 300 (see above, FIG. 4), and any of the variable components of the current balancing circuits of FIGS. 5A-5F may be controlled by the controller 400 to balance Iᵢₙ and Iₒᵤₜ. Additionally, a current balancing circuit may include more than one fixed capacitor, variable capacitor, fixed inductor, variable inductor, fixed resistor, variable resistor, diode, transistor, the like, or a combination thereof, coupled together in series and/or parallel. Any and all such suitable current balancing circuits with one or more variable components are within the scope of the disclosed embodiments.

FIG. 6 illustrates a graph illustrating experimental results for a current balancing circuit. The experimental results of FIG. 6 were obtained from a plasma processing system having a plasma chamber filled with Ar at a pressure of 10 mT and providing RF power to a resonator antenna at 300 W at a frequency of 26.95 MHz. Currents Iᵢₙ and Iₒᵤₜ are plotted versus the capacitance of the variable capacitor 312 (see above, FIG. 4). As illustrated in FIG. 6, matching values for the currents Iᵢₙ and Iₒᵤₜ are achieved with a matching capacitance C_{match} of about 280 pF of the variable capacitor 312.

FIG. 7 illustrates a process flow chart diagram of a method 500 for achieving current balancing in a resonator antenna system, in accordance with some embodiments. The method 500 may be executed during a plasma process, such as by a controller 400 checking Iᵢₙ and Iₒᵤₜ at pre-determined intervals in order to detect a current imbalance.

In step 502, the controller 400 reads out Iᵢₙ and Iₒᵤₜ from the current sensors 310 and 320, as described above with respect to FIG. 4. Next, in step 504, the controller 400 checks if |Iᵢₙ−Iₒᵤₜ| is within a pre-determined tolerance (e.g., a range of 0 A to 0.1 A). If |Iᵢₙ−Iₒᵤₜ| is not within the pre-determined tolerance, the method 500 proceeds to step 506. If |Iᵢₙ−Iₒᵤₜ| is within the pre-determined tolerance, the method 500 proceeds to step 520.

In step 506, the controller 400 changes an adjustable parameter of a current balancing circuit such as the balancing capacitance C_{BAL} of a capacitor in the current balancing circuit (e.g., the variable capacitor 312 of the example current balancing circuit 300), as described above with respect to FIG. 4. However, rather than a capacitance, the controller 400 may change any adjustable parameter of the current balancing circuit (e.g., a capacitance, an inductance, a resistance, the like, or a combination thereof).

Next, in step 508, the controller reads the total impedance Z_{load} of the load coupled to the RF source 101 (e.g., the total impedance of the matching circuit 200, resonator antenna 102, current balancing circuit 300, and current sensors 310 and 320) and phase ϕ of the RF power, such as from an IV sensor that is part of the RF source 101, as described above with respect to FIG. 1. The total impedance Z_{load} may be useful for adjusting the impedance of the matching circuit 200 to reduce reflected power.

In the following step 510, to ensure that the RF source 101 is operating at the resonant frequency of the resonator antenna 102 after changes have been made in the balancing capacitance C_{BAL} (see above, step 506), the controller 400 checks if the phase ϕ is less than, for example, ±5°. (±5° is included as an example, and the controller may also check if the phase ϕ is less than ±2°, ±1° or any other values less than ±10°.) If the phase ϕ is not less that ±5°, the method proceeds to step 512, in which the controller instructs the RF source 101 to change the RF generation frequency. The method then returns to step 510 to check again if the phase § is less that ±5°. Once the controller finds that the phase ϕ is less that +5°, the method proceeds to step 514.

In step 514, the controller 400 checks if |Iᵢₙ−Iₒᵤₜ| has decreased (such as due to the changing of an adjustable parameter such as a balancing capacitance C_{BAL}). If |Iᵢₙ−Iₒᵤₜ| has not decreased, the method proceeds to step 516. If |Iᵢₙ−Iₒᵤₜ| has decreased, the method proceeds to step 518.

In step 516, the controller 400 changes the adjustable parameter (e.g., the balancing capacitance C_{BAL}) in the opposite direction as it was changed in the previous step 506. The method then returns to step 504 for the controller 400 to again check if |Iᵢₙ−Iₒᵤₜ| is within the pre-determined tolerance.

In step 518, the controller 400 changes the adjustable parameter (e.g., the balancing capacitance C_{BAL}) in the same direction as it was changed in the previous step 506. The method then returns to step 504 for the controller 400 to again check if |Iᵢₙ−Iₒᵤₜ| is within the pre-determined tolerance.

In step 520, after the controller 400 has found that |Iᵢₙ−Iₒᵤₜ| is within the pre-determined tolerance, impedance matching has been achieved by the current balancing circuit 300 and the currents in the inner coil section 102A and the outer coil section 102B are approximately equal (see above, FIG. 4), which may be advantageous for achieving plasma uniformity. The controller 400 may continue to monitor Iᵢₙ and Iₒᵤₜ while the plasma process continues and execute the method 500 again if another current imbalance is detected.

FIG. 8 illustrates a process flow chart diagram of a method 600 for a plasma process, in accordance with some embodiments. In step 602, a resonator antenna 102 is powered with an RF source 101, as described above with respect to FIG. 1. The resonator antenna 102 is above a plasma chamber (e.g., a plasma processing chamber 106). The RF source 101 is coupled to the resonator antenna 102 through a first current sensor 310 and the resonator antenna 102 is coupled to a ground terminal 120 through a second current sensor 320, as described above with respect to FIG. 4.

In step 604, the first current sensor 310 measures a first current (e.g., Iᵢₙ) and the second current sensor 320 measures a second current (e.g., Iₒᵤₜ), as described above with respect to FIG. 4. In step 606, a variable component (e.g., a variable capacitor 312) of a current balancing circuit 300 is adjusted based on a difference between the first current and the second current, as described above with respect to FIG. 4. The current balancing circuit 300 is coupled between the second current sensor 320 and the ground terminal 120.

In step 608, a plasma process is performed in the plasma chamber with a plasma generated by the resonator antenna 102, as described above with respect to FIG. 1. While the plasma process continues, the first current sensor 310 and the second current sensor 320 may continue to monitor the first current and the second current as in step 604, and the method 600 may return to step 606 to adjust the variable component again if an imbalance is detected again between the first current and the second current, as described above with respect to step 520 of FIG. 7.

Example embodiments of the invention are described below. Other embodiments can also be understood from the entirety of the specification as well as the claims filed herein.

Example 1. A resonator antenna system for a plasma processing tool, the resonator antenna system including: a resonator antenna coupled to a RF source at a first point on the resonator antenna; a current balancing circuit coupled to the resonator antenna at a second point on the resonator antenna, the current balancing circuit including a first variable component, the current balancing circuit being further coupled to a ground terminal; a first current sensor coupled between the RF source and the resonator antenna; and a second current sensor coupled between the current balancing circuit and the resonator antenna.

Example 2. The resonator antenna system of example 1, further including a controller coupled to the first current sensor, the second current sensor, and the first variable component, the controller being configured to balance a first current measured by the first current sensor with a second current measured by the second current sensor by adjusting a parameter of the first variable component.

Example 3. The resonator antenna system of one of examples 1 or 2, where the first variable component is a variable capacitor.

Example 4. The resonator antenna system of one of examples 1 or 2, where the first variable component is a variable inductor.

Example 5. The resonator antenna system of one of examples 1 or 2, where the first variable component is a variable resistor.

Example 6. The resonator antenna system of one of examples 1 to 5, where the current balancing circuit further includes a second variable component, the second variable component being a different type of component from the first variable component.

Example 7. The resonator antenna system of one of examples 1 to 6, where the resonator antenna is a flat coil antenna.

Example 8. The resonator antenna system of example 7, further including an absorption coil surrounded by the resonator antenna.

Example 9. The resonator antenna system of one of examples 1 to 8, where an inner end and an outer end of the resonator antenna are electrically floating.

Example 10. The resonator antenna system of one of examples 1 to 9, where a frequency of the RF source is at least 13.56 MHz.

Example 11. The resonator antenna system of one of examples 1 to 10, where the RF source is pulse-modulated at a frequency range of 10 Hz to 1000 kHz.

Example 12. The resonator antenna system of one of examples 1 to 11, where the RF source is pulse-modulated with a duty cycle in a range of 10% to 90%.

Example 13. The resonator antenna system of one of examples 1 to 12, further including a matching circuit coupled between the RF source and the first current sensor, where the matching circuit is separate from the current balancing circuit.

Example 14. A method for plasma processing, the method including: powering a resonator antenna with an RF source, the resonator antenna being above a plasma chamber, the RF source being coupled to the resonator antenna through a first current sensor, the resonator antenna being coupled to a ground terminal through a second current sensor; measuring a first current with the first current sensor and a second current with the second current sensor; based on a difference between the first current and the second current, adjusting a variable component of a current balancing circuit, the current balancing circuit being coupled between the second current sensor and the ground terminal; and performing a plasma process in the plasma chamber with a plasma generated by the resonator antenna.

Example 15. The method of example 14, where the variable component is a variable capacitor.

Example 16. The method of one of examples 14 or 15, where after adjusting the variable component, the difference between the first current and the second current is less than 0.1 A.

Example 17. A plasma processing system including: a plasma processing chamber; a resonator antenna outside the plasma processing chamber, the resonator antenna coupled to an RF source at a first point on the resonator antenna, a matching circuit and a first current sensor being coupled between the RF source and the first point; and a ground terminal coupled to a second point on the resonator antenna, a length of the resonator antenna from the second point to an end of the resonator antenna being equal to a quarter-wavelength of a frequency of operation of the resonator antenna, a second current sensor and a filter circuit being coupled between the second point and the ground terminal.

Example 18. The plasma processing system of example 17, where the filter circuit is an LC circuit.

Example 19. The plasma processing system of example 18, where the LC circuit includes a variable capacitor and a fixed inductor.

Example 20. The plasma processing system of example 18, where the LC circuit includes a variable inductor and a fixed capacitor.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A resonator antenna system for a plasma processing tool, the resonator antenna system comprising:
a resonator antenna coupled to a RF source at a first point on the resonator antenna;
a current balancing circuit coupled to the resonator antenna at a second point on the resonator antenna, the current balancing circuit comprising a first variable component, the current balancing circuit being further coupled to a ground terminal;
a first current sensor coupled between the RF source and the resonator antenna; and
a second current sensor coupled between the current balancing circuit and the resonator antenna.

2. The resonator antenna system of claim 1, further comprising a controller coupled to the first current sensor, the second current sensor, and the first variable component, the controller being configured to balance a first current measured by the first current sensor with a second current measured by the second current sensor by adjusting a parameter of the first variable component.

3. The resonator antenna system of claim 1, wherein the first variable component is a variable capacitor.

4. The resonator antenna system of claim 1, wherein the first variable component is a variable inductor.

5. The resonator antenna system of claim 1, wherein the first variable component is a variable resistor.

6. The resonator antenna system of claim 1, wherein the current balancing circuit further comprises a second variable component, the second variable component being a different type of component from the first variable component.

7. The resonator antenna system of claim 1, wherein the resonator antenna is a flat coil antenna.

8. The resonator antenna system of claim 7, further comprising an absorption coil surrounded by the resonator antenna.

9. The resonator antenna system of claim 1, wherein an inner end and an outer end of the resonator antenna are electrically floating.

10. The resonator antenna system of claim 1, wherein a frequency of the RF source is at least 13.56 MHz.

11. The resonator antenna system of claim 1, wherein the RF source is pulse-modulated at a frequency range of 10 Hz to 1000 kHz.

12. The resonator antenna system of claim 1, wherein the RF source is pulse-modulated with a duty cycle in a range of 10% to 90%.

13. The resonator antenna system of claim 1, further comprising a matching circuit coupled between the RF source and the first current sensor, wherein the matching circuit is separate from the current balancing circuit.

14. A method for plasma processing, the method comprising:
powering a resonator antenna with an RF source, the resonator antenna being above a plasma chamber, the RF source being coupled to the resonator antenna through a first current sensor, the resonator antenna being coupled to a ground terminal through a second current sensor;
measuring a first current with the first current sensor and a second current with the second current sensor;
based on a difference between the first current and the second current, adjusting a variable component of a current balancing circuit, the current balancing circuit being coupled between the second current sensor and the ground terminal; and
performing a plasma process in the plasma chamber with a plasma generated by the resonator antenna.

15. The method of claim 14, wherein the variable component is a variable capacitor.

16. The method of claim 14, wherein after adjusting the variable component, the difference between the first current and the second current is less than 0.1 A.

17. A plasma processing system comprising:
a plasma processing chamber;
a resonator antenna outside the plasma processing chamber, the resonator antenna coupled to an RF source at a first point on the resonator antenna, a matching circuit and a first current sensor being coupled between the RF source and the first point; and
a ground terminal coupled to a second point on the resonator antenna, a length of the resonator antenna from the second point to an end of the resonator antenna being equal to a quarter-wavelength of a frequency of operation of the resonator antenna, a second current sensor and a filter circuit being coupled between the second point and the ground terminal.

18. The plasma processing system of claim 17, wherein the filter circuit is an LC circuit.

19. The plasma processing system of claim 18, wherein the LC circuit comprises a variable capacitor and a fixed inductor.

20. The plasma processing system of claim 18, wherein the LC circuit comprises a variable inductor and a fixed capacitor.
